(19) United States
(12) Patent Application Publication
(10) Pub. No.: US 2009/0057700 A1
(43) Pub. Date: Mar. 5, 2009

(54) Light emitting element and a manufacturing method thereof

(76) Inventors: Yong Sung Jin, Seoul (KR); Jae hak Lee, Seoul (KR); Sang Kee Shee, Gyeonggi-do (KR)

Correspondence Address: THE NATH LAW GROUP, 112 South West Street, Alexandria, VA, 22314, US

(21) Appl. No.: 11/918,882

(22) PCT Filed: Apr. 20, 2006
(86) PCT No.: PCT/KR2006/001493

§ 371 Date: Oct. 19, 2007

(30) Foreign Application Priority Data
Apr. 20, 2005 (KR) 10-2005-0032834

(51) Int. Cl. H01L 33/00

(52) U.S. Cl. 257/98; 438/29; 257/E33.025; 257/E33.067

(57) ABSTRACT

A light emitting element and a method for manufacturing the same are disclosed. In accordance with the element and the method, the dielectric thin film including the embossed pattern partially covering the sapphire substrate prevents damage of a sapphire substrate that occurs during a texturing of the sapphire substrate and a defect of an epitaxial thin film formed in a subsequent process.

### TECHNICAL FIELD

The present invention relates, in general, to a light emitting element and a method for manufacturing the same and, more particularly, to a light emitting element having an improved light extraction efficiency and a method for manufacturing the same.

### BACKGROUND ART

Generally, a light emitting diode (LED) is a semiconductor device that emits an incoherent narrow-spectrum light when electrically biased in a forward direction. The LED is regarded as a next generation illuminating device replacing incandescent and fluorescent lamps. Particularly, as the LED is utilized as light sources having a long life span for a large LCD, the LED is expected to be in a great demand.

However, most of a light generated from the LED is confined therein due to a total reflection due to a difference between refractive indices of materials constituting the LED such as a sapphire substrate, an epitaxial layer and an epoxy.

The total reflection occurs at a boundary of media having different refractive indices when the light is traveling from the medium having a relatively high refractive index toward the medium having a relatively low refractive index. Total reflection is determined by Snell's law.

FIG. 1 is a schematic view illustrating Snell's law, wherein n₁ and n₂ are refractive indices of a first and a second media, respectively, and θ₁ and θ₂ are incidence and refraction angles, respectively. The refractive index n₁ of the first medium is assumed to be larger than the refractive index n₂ of the second medium.

Snell's law defines a relationship between the incidence angle and the refraction angle acting on the boundary of the media having the different refractive indices for a wave (light wave), which is expressed as an equation 1 below.

n₁ sin θ₁=n₂ sin θ₂ [Equation 1]

When the light travels from the medium having the high refractive index (a dense medium) to the medium having the low refractive index (a sparse medium), the refraction angle θ₂ becomes larger than the incidence angle θ₁ as shown in FIG. 1. If the incidence angle is greater than a critical angle θ_{c}, an entirety of the light is reflected at the boundary between the first medium and the second medium. Such phenomenon is referred to as the total reflection.

A sapphire substrate and a gallium nitride (GaN) layer employed in a gallium nitride-based LED widely used as a blue light source have refractive indices of 1.8 and 2.5, respectively, which differs greatly from that of an air having a refractive index of 1. The large difference in refractive indices causes the majority of the light generated in the LED to be trapped within the LED.

For instance, since the critical angle of a boundary between the gallium nitride (GaN) layer and the sapphire substrate is approximately 46 degrees, the light having the incident angle of more than 46 degrees is trapped within the gallium nitride (GaN) layer.

Similarly, the critical angle between the sapphire substrate and the air is 33.5 degrees and the critical angle between the gallium nitride (GaN) layer and the air is 23.6 degrees. Therefore, the light having the incident angle larger than 33.5 degrees is trapped in the sapphire substrate and the light having the incident angle larger than 23.6 degrees is trapped in the gallium nitride (GaN) layer.

As described above, the trapping of the light generated in the LED due to the total reflection at the boundary degrades an external quantum efficiency of the LED, thereby reducing a light output of the LED.

FIG. 2 is a perspective view schematically illustrating a structure of a conventional GaN-based LED.

Referring to FIG. 2, a typical GaN-based LED comprises a substrate 11, an n-type GaN layer 13, an active layer 14, a p-type GaN layer 15, a p-type transparent electrode 16, a p-electrode 17, and an n-electrode 18. During an operation, an electron-hole recombination occurs in the active layer 14 thereby emitting a light when an electric current flows through the p-electrode 17 and the n-electrode 18.

Generally, a MOCVD (Metal Organic Chemical Vapor Deposition) apparatus is used to grow the GaN layer 13 on the substrate 11. The substrate 11 is a sapphire substrate or a silicon carbide substrate.

First, a buffer layer (not shown) for aiding a growth of the n-type GaN layer 13 is formed on the substrate 11. The n-type GaN layer 13, the active layer 14 and the p-type GaN layer 15 are then sequentially grown thereon.

In the diode, the electrodes are formed on the p-type GaN layer and a lower portion of the substrate connected to the n-type GaN layer such that a current may flow through a p-n junction. However, the electrode cannot be formed on the substrate 11 because the sapphire substrate is an insulator. Therefore, the electrode should be formed directly on the n-type GaN layer 13.

In this regard, the p-type GaN layer 15, the active layer 14, and a portion of the n-type GaN layer 13 where the electrode is to be formed are removed and the n-electrode 18 is then formed on an exposed portion of the n-type GaN layer 13. Because the light is generated at the p-n junction, the p-electrode 17 is formed at a comer of the p-type transparent electrode 16 so that the light is not blocked by the electrode.

In addition, it is difficult for the current to flow uniformly throughout the p-type GaN layer 15 because a resistance of the p-type GaN layer 15 is larger than that of the n-type GaN layer 13. In order to prevent this, the transparent electrode is deposited over an entire surface of the p-type GaN layer 15 to facilitate the current flow through the p-type GaN layer 15.

On the other hand, a texturing method is employed in order to reduce a loss of the light due a total reflection of the light generated in the GaN-based LED. In accordance with the method, the light generated in the LED is scattered to change a light traveling path so as to increase a possibility of the light escaping from the diode.

The texturing method may be classified into texturing a surface of the gallium nitride (GaN) layer and texturing a surface of the sapphire substrate.

When the surface of the gallium nitride (GaN) layer is textured, the surface of the gallium nitride (GaN) layer becomes coarse, thereby degrading the formation of the p-electrode. Therefore, an overall electrical characteristic of the LED is degraded.

The texturing of the surface of the sapphire substrate provides a coarseness of the surface as described with reference to FIG. 3.

FIG. 3 is a cross-sectional view schematically illustrating a cross-section of the conventional LED shown in FIG. 2. For the convenience of description, a cross-section of the LED similar to the GaN-based LED shown in FIG. 2 is illustrated wherein like reference numerals denotes like components.

As shown in FIG. 3, the GaN-based LED 10 in accordance with the comparative example comprises a sapphire substrate 11, a GaN buffer layer 12, an n-type GaN layer 13, an active layer 14, a p-type GaN layer 15, a current spreading layer 16, a p-electrode 17, and an n-electrode 18. During an operation, an electron-hole recombination occurs in the active layer 14 thereby emitting a light when an electric current flows through the p-electrode 17 and the n-electrode 18.

However, the texturing method is difficult to be applied to the sapphire substrate 11 which is not easily etched. In addition, because an etched surface of the sapphire substrate is coarse, a problem occurs during an epitaxial growth. The GaN buffer layer 12 plays an important role during the epitaxial growth of the n-type GaN layer 13.

Typically, the buffer layer 12 grown at a temperature ranging from 500 to 600° C. undergoes a phase change by annealing at a temperature as high as approximately 1050° C. prior to being grown to a predetermined thickness. Thereafter, the buffer layer is grown to the predetermined thickness. It is important to control a size of an island by the phase change after the annealing of the buffer layer 12 in order to obtain an epitaxial thin film of a high quality. The controlling of the size of the island greatly depends on a surface uniformity of the buffer layer 12.

Since the sapphire substrate shown in FIG. 3 has a random coarse surface, the buffer layer 12 also has a coarse surface and a non-uniform thickness. Therefore, the size of the island of the buffer layer 12 cannot be easily controlled after the annealing of the buffer layer 12.

The phenomenon is aggravated on an embossed pattern of the sapphire substrate. Specifically, it is difficult to obtain a low defective density when the buffer layer is epitaxially grown on the patterned sapphire substrate and a uniformity of a characteristic of a device on a wafer is degraded due to a high non-uniformity of a coarseness of the surface, thereby reducing a yield and a productivity.

### DISCLOSURE

### Technical Problem

In order to solve the foregoing problems, it is an object of the present invention to provide a GaN-based light emitting element and a method for fabricating the same by improving a light extraction efficiency of an LED of a high intensity.

### Technical Solution

There is provided a light emitting element, comprising: a substrate; a dielectric thin film disposed on the substrate, the dielectric thin film including an embossed pattern; a buffer layer covering the substrate and the dielectric thin film; a first GaN-based layer disposed on the buffer layer, the first GaN-based layer having a first thickness in a first region and a second thickness in a second region; a first electrode disposed on the second region of the first GaN-based layer; an active layer disposed on the first region of the first GaN-based layer; a second GaN-based layer disposed on the active layer; and a second electrode disposed on the second GaN-based layer.

Preferably, the substrate comprises one of a sapphire, a silicon, a quartz, an AlGaInN, an AlGaN, an InGaN, a GaN, an AlN, a BN, a CrN, a TiN, and a GaAs.

In addition, the first GaN-based layer preferably comprises a compound of n nitrogen and one of an aluminum, a gallium, a indium, a boron, a thallium, and combinations thereof.

It is preferable that the first GaN-based layer is doped with n-type and p-type impurities and the second GaN-based layer is doped with the n-type and p-type impurities to have a conductivity opposite to that of the first GaN-based layer to form a p-n junction.

In addition, the dielectric thin film preferably comprises a silicon oxynitride (SiOₓN_{y}) or an aluminum oxide.

It is preferable that the SiOₓN_{y} has a refractive index ranging from 1.4 to 2 or from 1.6 to 1.9.

Preferably, the embossed pattern is disposed to form a grid.

Preferably, the embossed pattern has a shape of a circle or a polygon having n number of sides, and a cross-section of the embossed pattern has a shape of a truncated ellipse, a truncated circle, a bell, a mongolian tent, a triangle or a polygon.

It is preferable that the embossed pattern is disposed to form a grid, the embossed pattern having a shape of a circle or a polygon being disposed at a vertex of the grid pattern.

Preferably, the dielectric thin film comprises the embossed pattern having a combination of a grid pattern and a circular pattern at a vertex of the grid pattern.

There is also provided a method for fabricating a light emitting element, comprising steps of: (a) forming a dielectric thin film including an embossed pattern on a substrate; (b) sequentially growing a buffer layer, a first GaN-based layer, an active layer and a second GaN-based layer on the substrate and the dielectric thin film; (c) depositing a current spreading layer on the second GaN-based layer and forming an ohmic contact via an annealing process; (d) removing a portion of the current spreading layer, and the second GaN-based layer, the active layer and a predetermined thickness of the first GaN-based layer thereunder; and (e) depositing a first electrode on an exposed portion of the first GaN layer and a second electrode on the current spreading layer.

Preferably, the step (a) comprises: (a-1) depositing the dielectric thin film on the substrate; (a-2) forming a photoresist film pattern; (a-3) reflowing the photoresist film pattern; (a-4) transcribing the reflowed photoresist pattern into the dielectric thin film by etching the dielectric thin film to form the embossed pattern; and (a-5) conducting a wet back etching process using a buffered oxide etchant to remove a portion of the dielectric thin film between embossed pattern.

It is preferable that the dielectric thin film comprises a silicon oxynitride (SiOₓN_{y}) or an aluminum oxide.

Preferably, the substrate comprises a sapphire and the dielectric thin film comprise a silicon oxynitride film (SiOₓN_{y}) having a refractive index of 1.78.

It preferable that the silicon oxynitride (SiOₓN_{y}) thin film has a composition determined by a ratio of an N₂O gas and an NH₃ gas or a ratio of an N₂ gas and an O₂ gas added to a SiH₄ gas.

Preferably, the thin film comprising the aluminum oxide is formed via a sputtering process, a CVD process or an evaporation process.

### ADVANTAGEOUS EFFECTS

In accordance with the present invention, the dielectric thin film including the embossed pattern is partially formed between the sapphire substrate and the epitaxial thin film to prevent the epitaxial growth on the dielectric thin film while allowing the epitaxial thin film to grow only on the exposed and undamaged surface of the sapphire substrate so that the epitaxial thin film of the high quality may be obtained and that the scattering of the light is maximized to improve the light extraction efficiency of the LED. Particularly, in accordance with the present invention, the defect of the epitaxial thin film may be prevented when the epitaxial thin film is epitaxially grown on the coarse surface of the textured sapphire substrate.

Furthermore, in accordance with the present invention, the total reflection of the light generated in the active layer of the LED may be reduced, thereby improving the light extraction efficiency of the LED.

Moreover, in accordance with the present invention, a reliability and productivity of the fabrication process of the embossed pattern is improved because the fabrication process of the embossed pattern is similar to a conventional silicon process.

### DESCRIPTION OF DRAWINGS

FIG. 1 is a schematic view illustrating Snell's law.

FIG. 2 is a perspective view schematically illustrating a structure of a conventional GaN-based LED.

FIG. 3 is a cross-sectional view schematically illustrating the structure of the conventional GaN-based LED shown in FIG. 2.

FIG. 4 is a cross-sectional view schematically illustrating a GaN-based LED according to the present invention.

FIGS. 5 and 6 are a plane view and a cross-sectional view respectively, showing a GaN-based LED in accordance with a first embodiment of the present invention.

FIG. 7 is a graph illustrating a relationship between a refractive index and an oxygen content of a SiOₓN_{y} dielectric thin film.

FIGS. 8 and 9 are a plane view and a cross-sectional view respectively, showing a structure of a GaN-based LED in accordance with a second embodiment of the present invention.

FIGS. 10 and 11 are a plane view and a cross-sectional view respectively, showing a structure of a GaN-based LED in accordance with a third embodiment of the present invention.

FIGS. 12 to 14 are a plane view and a cross-sectional view respectively, showing a structure of a GaN-based LED in accordance with a fourth embodiment of the present invention.

FIGS. 15 to 19 are cross-sectional views showing a method for fabricating the LED shown in FIG. 4.

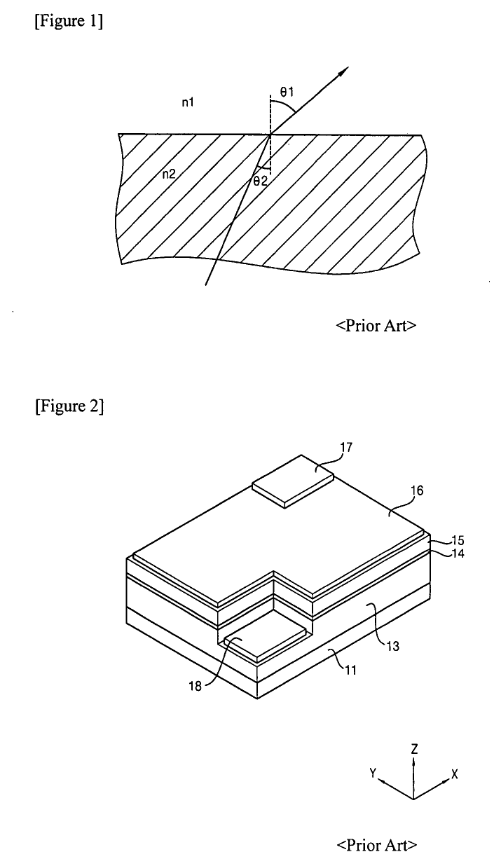

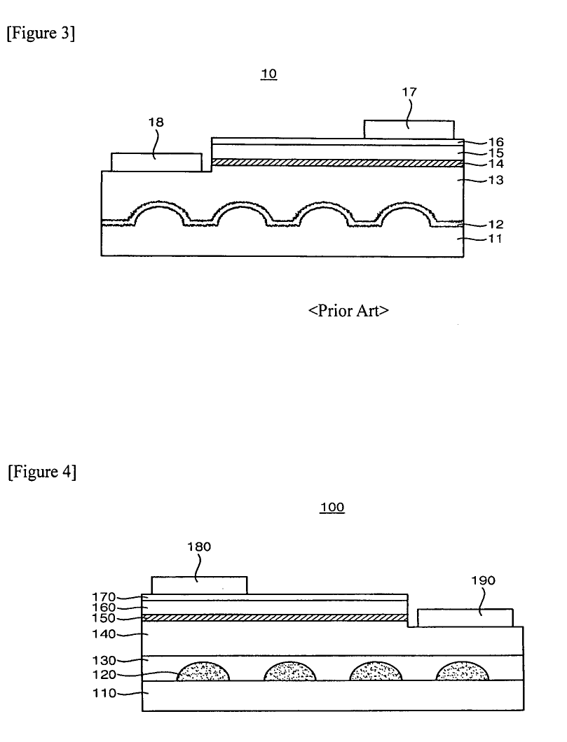

### BEST MODE

In order to achieve the above object of the present invention, there is provided a light emitting element comprising a substrate, a dielectric thin film, a buffer layer, a first GaN layer, a first electrode, an active layer, a second GaN layer, and a second electrode. A refractive index of the dielectric thin film is substantially same as that of the substrate, and the dielectric thin film includes an embossed pattern disposed on a portion of the substrate. The buffer layer covers an exposed portion of the substrate and the dielectric thin film. The first GaN layer is disposed on the buffer layer to have a first thickness in a first region of the buffer layer and a second thickness in a second region thereof wherein the first thickness is greater than the second thickness. The first electrode is formed on the second region of the first GaN layer while the active layer is formed on the first region of the first GaN layer. The second GaN layer is deposited on the active layer. The second electrode is formed on the second GaN layer.

In order to achieve the object of the present invention, there is provided a method for fabricating a light emitting element, comprising steps of: (a) forming a dielectric thin film including an embossed pattern on a substrate; (b) sequentially growing a buffer layer, a first GaN-based layer, an active layer and a second GaN-based layer on the substrate and the dielectric thin film; (c) depositing a current spreading layer on the second GaN-based layer and forming an ohmic contact via an annealing process; (d) removing a portion of the current spreading layer, and the second GaN-based layer, the active layer and a predetermined thickness of the first GaN-based layer thereunder; and (e) depositing a first electrode on an exposed portion of the first GaN layer and a second electrode on the current spreading layer.

In accordance with the light emitting element and the manufacturing method thereof, a silicon oxynitride (SiOₓN_{y}) thin film including an embossed pattern is disposed between the substrate and the GaN layer to improve a light extraction efficiency.

A detailed description of the present invention will be given with reference to the accompanying drawings.

### MODE FOR INVENTION

FIG. 4 is a cross sectional view schematically illustrating a GaN-based LED in accordance with a first embodiment of the present invention.

As shown in FIG. 4, a GaN-based LED 100 in accordance with the first embodiment of the present invention comprises a substrate 110, a dielectric thin film 120, a buffer layer 130, an n-type GaN layer 140, an active layer 150, a p-type GaN layer 160, a current spreading layer 170, a p-electrode 180, and an n-electrode 190. During an operation, an electron-hole recombination occurs in the active layer 150, to generate a light when a current flows through the p-electrode 180 and the n-electrode 190

Generally, a MOCVD (Metal Organic Chemical Vapor Deposition) apparatus is used to grow the GaN layer on the substrate 110. The substrate 110 comprises, but not limited to a sapphire substrate or a silicon carbide substrate. The substrate 110 may comprises one of a quartz, an AlGaInN, an AlGaN, an InGaN, an AlN, a BN, a CrN, a TiN, and a GaAs.

The dielectric thin film 120 having a predetermined pattern is disposed on the substrate 110. The dielectric thin film 120 has an embossed pattern covering a portion of the substrate 110 and exposing a remaining portion of the substrate 110. Preferably, a refractive index of the dielectric thin film 120 is substantially the same as that of the substrate 110. The dielectric thin film 120 may comprises a silicon oxynitride thin film or an aluminum oxide thin film. Generally, the silicon oxynitride thin film may share advantages of a SiO₂ thin film and a Si₃N₄ thin film, and parameters thereof such as a dielectric constant, the refractive index, and a coefficient of thermal expansion may be controlled a gas flow rate. A description SiON will be given later.

The buffer layer 130 disposed is disposed on the substrate 110. The buffer layer 130 covers the portion of the substrate 110 exposed by the dielectric thin film 120 and the dielectric thin film 120.

In addition, the n-type GaN layer 140, the active layer 150 and the p-type GaN layer 160 are sequentially disposed on the buffer layer 130. Generally, the electrodes are disposed on the p-type GaN layer and a lower portion of the substrate connected to the n-type GaN layer such that the current may flow through a p-n junction. However, the electrode cannot be formed on the substrate 110 used as a substrate for the GaN diode because the sapphire is an insulator. Therefore, the electrode should be formed directly on the n-type GaN layer 140.

In this regard, the n-type GaN layer 140, the active layer 150 and a portion of the p-type GaN layer 160 where the electrode is to be formed are removed and the n-electrode 190 is then disposed on an exposed portion of the n-type GaN layer 140. Accordingly, the n-type GaN layer 140 has a first thickness in a first region of the buffer layer 130 and a second thickness in a second region of the buffer layer 130 wherein the first thickness is greater than the second thickness. The n-type GaN layer 140 may include a compound of a nitrogen and one of an aluminum, a gallium, an indium, a boron, a thallium and combinations thereof.

The p-electrode 180 is disposed at a comer of the current spreading layer 170 because the light is emitted from the p-n junction such that the light is not blocked.

When both the p-electrode 180 and the n-electrode 190 are disposed at an upper portion, a current distribution is not uniform compared to a general diode structure wherein the electrodes are disposed on different surfaces parallel to each other.

In addition, it is difficult for the current to flow uniformly throughout the p-type GaN layer 160 because a resistance of the p-type GaN layer 160 is larger than that of the n-type GaN layer 140.

In order to prevent this, the current spreading layer 170 which is a thin transparent electrode is disposed over an entire surface of the p-type GaN layer 160 to facilitate the current flow throughout the p-type GaN layer 160.

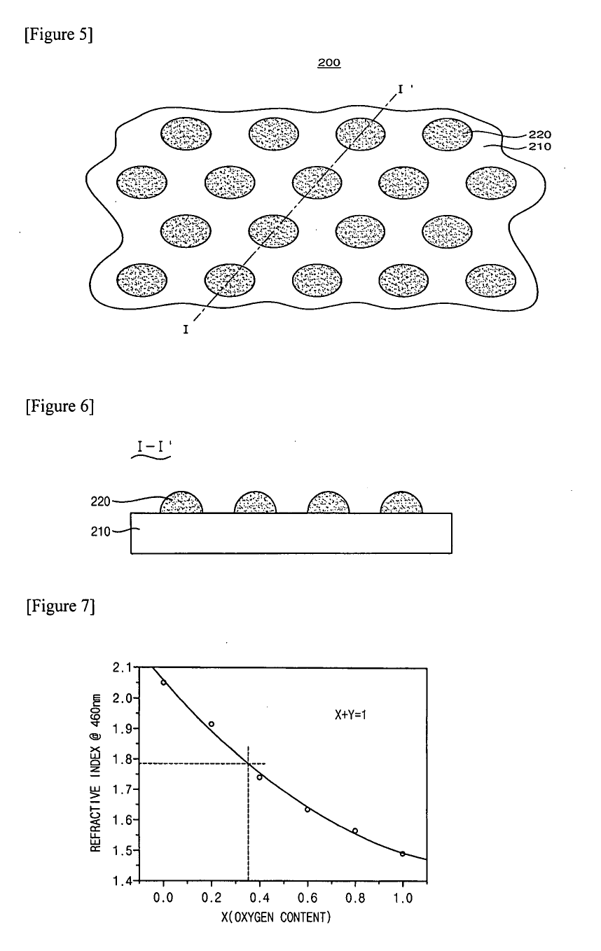

FIGS. 5 and 6 are a plane view and a cross sectional view respectively, showing the GaN-based LED in accordance with a first embodiment of the present invention wherein an SiON dielectric thin film includes an embossed pattern having a cross-section of a hemisphere. For convenience of description, only the dielectric thin film disposed on the substrate is shown.

As shown in FIGS. 5 and 6, an LED 200 in accordance with the first embodiment of the present invention comprises a substrate 210 and a dielectric thin film 220 having a hemispherical embossed pattern disposed on the substrate 210. A substantial thickness of the dielectric thin film 220 ranges from 1 to 5 μm, a substantial diameter thereof ranges from 1 to 10 μm and a distance therebetween ranges from 1 to 10 μm. The dielectric thin film 220 comprises a SiOₓN_{y} having a refractive index of approximately 1.78.

While FIG. 5 shows the dielectric thin film 220 including the hemispherical pattern having a same diameter, the dielectric thin film 220 may include the hemispherical pattern having various diameters. While FIG. 5 shows the dielectric thin film 220 having a uniform thickness, the dielectric thin film 220 may have various thicknesses.

Moreover, while FIG. 5 shows the dielectric thin film 220 including the hemispherical pattern having a uniform distance therebetween, the dielectric thin film 220 may include the hemispherical pattern having various distances therebetween.

In addition, while FIG. 5 shows the dielectric thin film 220 having a uniform radius of curvature, the dielectric thin film 220 may have various radii of curvature.

In addition, while FIG. 5 shows the dielectric thin film 220 including the hemispherical pattern having a uniform density, a density of the hemispherical pattern may be dense in one region and sparse in another region.

Moreover, while a cross-section of the dielectric thin film 220 is hemispherical, the cross-section thereof may be have a shape of a truncated ellipse, a truncated circle, a bell, a mongolian tent, a triangle or a polygon.

The GaN-based LED in accordance with the present invention employs the SiOₓN_{y} having the refractive index of approximately 1.78 as the dielectric thin film 220 to facilitate the formation of the embossed pattern. The SiOₓN_{y} is a dielectric material which is a composite of SiO₂ and SiN. The SiOₓN_{y} is has the refractive index ranging from 1.4 which is the refractive index of SiO₂ to 2.0 which is the refractive index of SiN. The refractive index of the SiOₓN_{y} ranges from 1.4 to 2.0 depending on relative amounts of SiO₂ and SiN.

FIG. 7 is a graph illustrating a relationship between a refractive index and an oxygen content of the dielectric thin film containing the SiOₓN_{y}. Particularly, the graph shows a variation of the refractive index of the SiOₓN_{y} according to the oxygen content x when the light having a wavelength of 460 nm travels.

As shown in FIG. 7, the oxygen content x is in inversely proportional to the refractive index. For instance, when the oxygen content is 0, 0.2, 0.4, 0.6, 0.8 and 1.0, the refractive indices of the dielectric thin film are 2.05, 1.9, 1.75, 1.65, 1.6 and 1.5, respectively.

It is preferable that the refractive index of the dielectric thin film is same as that of the substrate. Because the refractive index of the substrate, the sapphire substrate in particular, is 1.78, the SiOₓN_{y} having the refractive index of 1.78 is used as the dielectric thin film 220. As shown in the graph, x is 0.35 and y is 0.65.

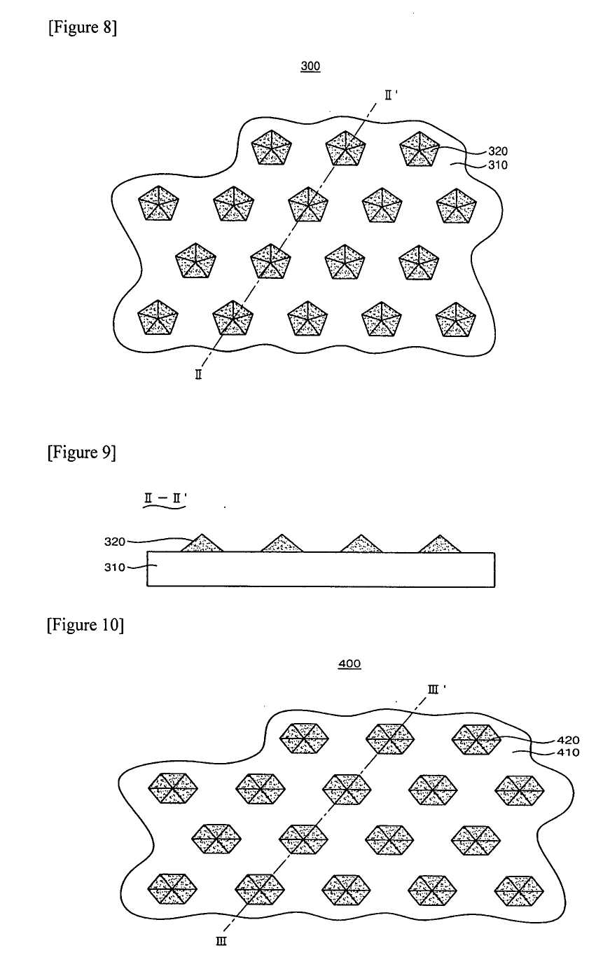

FIGS. 8 and 9 are a plane view and a cross-sectional view respectively, showing a structure of a GaN-based LED in accordance with a second embodiment of the present invention wherein a dielectric thin film includes a pentagonal embossed pattern comprising a SiON in particular. For convenience of description, only the dielectric thin film disposed on the substrate is shown.

As shown in FIGS. 8 and 9, an LED 300 in accordance with the second embodiment of the present invention comprises a substrate 310 and a dielectric thin film 320 having a pentagonal embossed pattern disposed on the substrate 310. A thickness of the pentagonal embossed pattern of the dielectric thin film 320 ranges from 1 to 5 μm, an average diagonal distance thereof ranges from 1 to 10 μm, and a distance therebetween ranges from 1 to 10 μm. The term “average diagonal distance” refers to a distance between a vertex and an opposing side. The dielectric thin film comprises a SiOₓN_{y} having a refractive index of approximately 1.78.

While the average diagonal distance of the dielectric thin film 320 shown in FIG. 8 is uniform, the dielectric thin film 320 may have various average diagonal distances. In addition, while FIG. 9 shows the dielectric thin film 320 having a uniform thickness, the dielectric thin film 320 may have various thicknesses.

Moreover, while FIGS. 8 and 9 show the dielectric thin film 320 including the pentagonal embossed pattern having a uniform distance therebetween, the dielectric thin film 320 may include the pentagonal embossed pattern having various distances therebetween. In addition, while FIGS. 8 and 9 show the dielectric thin film 220 including the pentagonal embossed pattern having a uniform density, a density of the pentagonal embossed pattern may be dense in one region and sparse in another region.

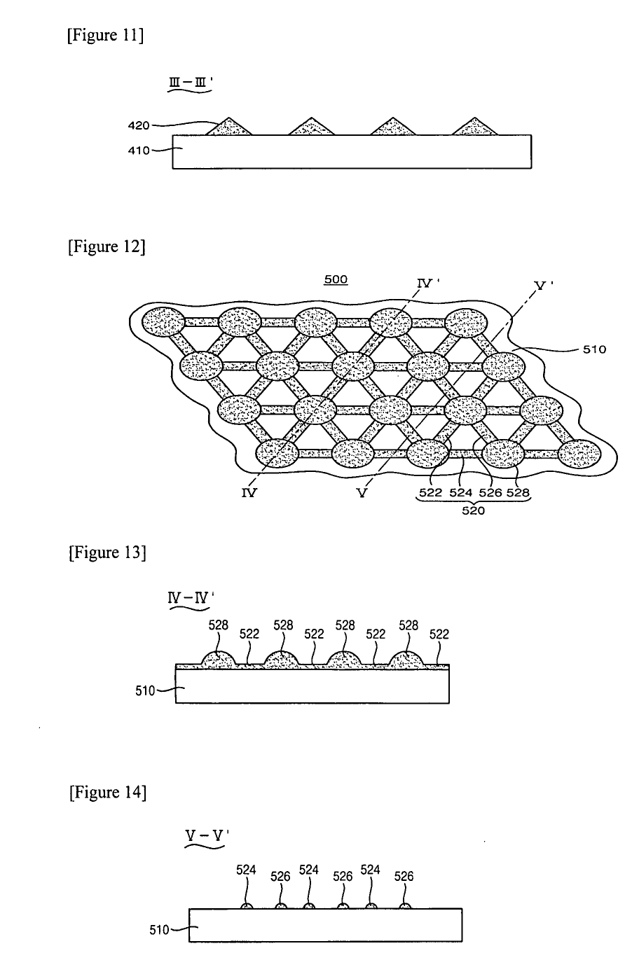

FIGS. 10 and 11 are a plane view and a cross-sectional view respectively, showing a structure of a GaN-based LED in accordance with a third embodiment of the present invention wherein a dielectric thin film includes a hexagonal embossed pattern comprising a SiON in particular. For convenience of description, only the dielectric thin film disposed on the substrate is shown.

As shown in FIGS. 10 and 11, an LED 400 in accordance with the third embodiment of the present invention comprises a substrate 410 and a dielectric thin film 420 having a hexagonal embossed pattern disposed on the substrate 410. A thickness of the hexagonal embossed pattern of the dielectric thin film 420 ranges from 1 to 5 μm, an average diagonal distance thereof ranges from 1 to 10 μm, and a distance therebetween ranges from 1 to 10 μm. The term “average diagonal distance” refers to a distance between a vertex and an opposing vertex. The dielectric thin film comprises a SiOₓN_{y} having a refractive index of approximately 1.78.

While the average diagonal distance of the dielectric thin film 420 shown in FIG. 10 is uniform, the dielectric thin film 420 may have various average diagonal distances. In addition, while FIG. 11 shows the dielectric thin film 420 having a uniform thickness, the dielectric thin film 420 may have various thicknesses.

Moreover, while FIGS. 10 and 11 show the dielectric thin film 420 including the hexagonal embossed pattern having a uniform distance therebetween, the dielectric thin film 420 may include the hexagonal embossed pattern having various distances therebetween. In addition, while FIGS. 8 and 9 show the dielectric thin film 220 including the hexagonal embossed pattern having a uniform density, a density of the hexagonal embossed pattern may be dense in one region and sparse in another region.

FIGS. 12 through 14 are a plane view and cross-sectional views respectively, showing a structure of a GaN-based LED in accordance with a fourth embodiment of the present invention wherein a dielectric thin film includes a combination of a hemispherical embossed pattern and a stripe pattern comprising a SiON in particular. For convenience of description, only the dielectric thin film disposed on the substrate is shown.

As shown in FIGS. 12 through 14, an LED 500 in accordance with the fourth embodiment of the present invention comprises a substrate 510 and a dielectric thin film 520 disposed on the substrate 510.

The dielectric thin film 520 comprises first, second and third sub-dielectric thin films 522, 524 and 526 of a stripe shape extending in different directions to form a triangular grid pattern and a circular fourth sub-dielectric thin films 528 disposed at a crossing of the first, second and third sub-dielectric thin films 522, 524 and 526. The first, second and third sub-dielectric thin films 522, 524 and 526 are disposed on the substrate 510 to have a predetermined width wherein a surface thereof is rounded. In addition, a diameter of the fourth sub-dielectric thin films 528 may be greater than the width of the first, second and third sub-dielectric thin films 522, 524 and 526 and the fourth sub-dielectric thin films 528 is disposed at the crossing of the first, second and third sub-dielectric thin films 522, 524 and 526.

A thickness of each of the first, second and third sub-dielectric thin films 522, 524 and 526 ranges from 1 to 5 μm, and a thickness of the fourth sub-dielectric thin films 528 may be larger than that of the first, second and third sub-dielectric thin films 522, 524 and 526. In addition, an average diameter of the fourth sub-dielectric thin films 528 ranges from 1 to 10 μm, and a substantial distance therebetween ranges from 1 to 10 μm. The first, second, third and fourth sub-dielectric thin films 522, 524, 526 and 528 comprises a SiOₓN_{y} having a refractive index of approximately 1.78.

Since the refractive index of the SiOₓN_{y} is same as that that of the sapphire substrate, a loss of the light at a boundary thereof may be ignored. Therefore, the example in accordance with the present invention wherein SiOₓN_{y} on the sapphire substrate and the conventional LED wherein the sapphire substrate is directly textured have a same optical characteristic.

However, the present invention is advantageous in that the texturing may be more easily carried out using the dielectric film compared to directly texturing the sapphire substrate, and in that an epitaxial thin film of a high quality may be obtained through a subsequent epitaxial growth.

Similar to an ELOG (Epitaxially Laterally Over Growth) process, the method is widely used for a growth of an epitaxial structure for a laser diode. Through the method, the substrate as well as the dielectric thin film remains undamaged and uniform.

Using a ray tracing simulator, an effect of such uniform elements on a light extraction efficiency of the LED is examined. In order to determine an optimal texturing pattern, the light extraction efficiency is calculated for a few patterns (no pattern, the stripe pattern, the hemispherical pattern, and the combination of the stripe pattern and the hemispherical pattern). Results of the calculation are given in Table 1, below.

TABLE 1

| Shape of dielectric | Extraction | |
|---|---|---|
| thin film | Efficiency (%) | Notes |
| No Pattern | 33.5 | |
| Stripe | 47.6 | Slope: 45° |
| | | Height: 1.5 μm |
| Hemisphere | 58.5 | Height: 1.5 μm |
| | | Radius: 4 μm |
| | | Interval: 10 μm |
| Stripe + Hemisphere | 64.9 | |

As shown in Table 1, the LED without the textured pattern has the light extraction efficiency of 33.5%.

However, the light extraction efficiencies are 47.6% for the LED having the stripe pattern, 58.5% for the LED having the hemispherical pattern, and 64.9% for the LED having the combination of the stripe pattern and the hemispherical pattern.

The result shows that more amount of the light may be extracted as a textured area increases. Therefore, it is advantageous for a fabrication of a high intensity LED when the density of the textured pattern increases within a range of the epitaxial growth.

Still referring to Table 1, the LED having the combination of the stripe pattern and the hemispherical pattern has the light extraction efficiency of at least 64.9%, which is twice that of the LED with no pattern.

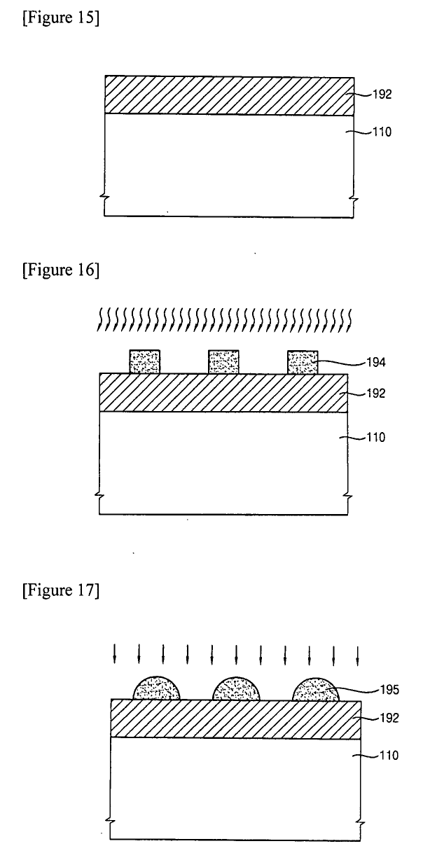

FIGS. 15 to 19 are cross-sectional views showing a method for fabricating the LED shown in FIG. 4.

Referring to FIG. 15, a silicon oxynitride (SiOₓN_{y}, refractive index of 1.78) thin film 192 having a thickness ranging from 1 to 3 μm is deposited on the substrate 110. The silicon oxynitride thin film 192 may be deposited via an ICPCVD (Inductive coupled plasma enhanced chemical vapor deposition) process, a PECVD (plasma enhanced chemical vapor deposition) process, an LPCVD (low pressure CVD) process or a sputtering process. However, it is preferable that the silicon oxynitride thin film 192 is deposited via the PECVD process. Alternatively, an aluminum oxide thin film may be deposited on the substrate 110 via a sputtering process, a CVD (Chemical Vapor Deposition) process, or an evaporation process.

In order to deposit the SiOₓN_{y} thin film via the PECVD process, an N₂O gas and an NH₃ gas may be added to a SiH₄ gas. The N₂O gas is an oxygen source and the NH₃ gas a nitrogen source. Thus, the SiOₓN_{y} thin film having a desired composition may be obtained by controlling the ratio of N₂O and NH₃.

Referring to FIG. 16, a photoresist (PR) 194 is coated on a resulting structure of the process shown in FIG. 15 and then patterned via a photolithographic process. The pattern may have various shapes. As an example, a mask having a circular mask pattern is used for the photolithography. A photoresist pattern including a cylindrical pattern having a predetermined distance therebetween is formed using the mask. Preferably, a radius of the cylindrical pattern ranges from 1 to 10 μm and a thickness thereof ranges from 1 to 5 μm.

Referring to FIG. 17, the photoresist pattern is reflowed to form a hemispherical photoresist pattern 195. Specifically, the photoresist pattern is baked on a hot plate or in an oven at a temperature ranging from 140 to 160° C. for a time ranging from 3 to 10 minutes. The time for baking may be controlled to form a photoresist pattern 195 having a hemispherical embossed pattern.

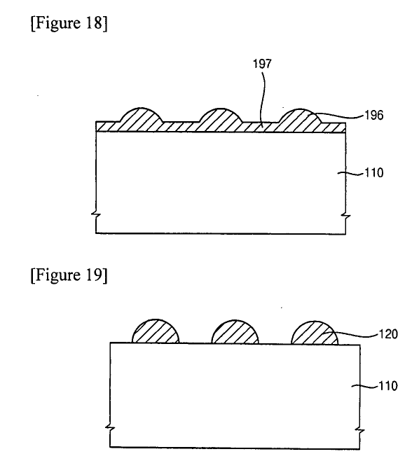

Referring to FIG. 18, the photoresist pattern 195 is transcribed to the SiOₓN_{y} thin film to form a silicon oxynitride thin film pattern 196. In order to transcribe the photoresist pattern 195, the SiOₓN_{y} thin film may be etched via an RIE (Reactive Ion Etching) process or an ICP-RIE (Inductive Coupled Plasma RIE) process. The silicon oxynitride thin film pattern 196 includes a residual film 197.

It is preferable that the photoresist pattern and the SiOₓN_{y} thin film are etched at a same etching ratio. However, the etching ratio of the photoresist pattern and the SiOₓN_{y} thin film may range from 1 to 2. A CF₄ gas and an O₂ gas are used as an etching gas, and a small amount of an argon gas (Ar) may be added for a stability of a plasma. Instead of the CF₄ gas, a gas containing a fluorine such as a CHF₃ gas and a SF₆ gas may be used. By adjusting a ratio of the CF₄ gas and the O₂ gas, the etching ratio of the photoresist pattern and the SiOₓN_{y} thin film may be selected. The etching is carried out until an entirety of the photoresist pattern is etched. However, the SiOₓN_{y} thin film in a planar region other than the cylindrical pattern is not completely removed and remains as the residual film having a thickness ranging from 10 to 50 nm.

Referring to FIG. 19, a wet chemical back etching process is carried out using a buffered oxide etchant to remove the residual film 197 comprising the SiOₓN_{y}, thereby forming the dielectric thin film 120 having the embossed pattern wherein the refractive index of the dielectric thin film 120 is substantially same as that of the substrate 110. Accordingly, the sapphire substrate having a uniform plasma-resistant surface is obtained in accordance with the present invention.

The method for forming the SiOₓN_{y} embossed pattern on the substrate 110 is described above. Conventional fabrication processes may be carried out after forming the SiOₓN_{y} embossed pattern to fabricate the LED.

That is, the GaN buffer layer 130, the n-type GaN 140, the MQW (multi quantum well) active layer 150, and the p-type GaN layer 160 are sequentially formed on the silicon oxynitride thin film disposed on the substrate 110 via the MOCVD (Metal organic CVD) process.

Thereafter, the current spreading layer 170 is deposited over the p-type GaN layer 160. The current spreading layer 170 and the p-type GaN layer 160 forms an ohmic contact and the current spreading layer 170 may comprise a Ni/Au, a Pd/Au or a Pt/Au. The current spreading layer 170 may be deposited via the evaporation process to have a thickness of approximately 10 nm.

Thereafter, the ohmic contact is formed via an annealing process. A portion at which an n-contact is to be formed is then mesa etched, and Ti/Al/Ti/Au or Cr/Ni/Au are sequentially deposited to form the n-electrode 190. Finally, Cr/Ni/Au are deposited to form the p-electrode 180, thereby completing the fabrication of the GaN-based LED.

While the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

### INDUSTRIAL APPLICABILITY

In accordance with the present invention, the GaN-based LED having the improved light extraction efficiency may be fabricated by depositing the silicon oxynitride (SiOₓN_{y}) thin film having a refractive index substantially identical to that of the sapphire substrate, patterning the silicon oxynitride thin film by the photolithography, and then epitaxially growing the epitaxial thin film.

In addition, in accordance with the present invention, the dielectric thin film including the embossed pattern is partially formed between the sapphire substrate and the epitaxial thin film to prevent the epitaxial growth on the dielectric thin film while allowing the epitaxial thin film to grow only on the exposed and undamaged surface of the sapphire substrate so that the epitaxial thin film of the high quality may be obtained and that the scattering of the light is maximized to improve the light extraction efficiency of the LED.

Particularly, in accordance with the present invention, the defect of the epitaxial thin film may be prevented when the epitaxial thin film is epitaxially grown on the coarse surface of the textured sapphire substrate.

Furthermore, in accordance with the present invention, the total reflection of the light generated in the active layer of the LED may be reduced, thereby improving the light extraction efficiency of the LED.

Moreover, in accordance with the present invention, a reliability and productivity of the fabrication process of the embossed pattern is improved because the fabrication process of the embossed pattern is similar to a conventional silicon process.

1. A light emitting element, comprising:
a substrate;
a dielectric thin film disposed on the substrate, the dielectric thin film including an embossed pattern;
a buffer layer covering the substrate and the dielectric thin film;
a first GaN-based layer disposed on the buffer layer, the first GaN-based layer having a first thickness in a first region and a second thickness in a second region;
a first electrode disposed on the second region of the first GaN-based layer;
an active layer disposed on the first region of the first GaN-based layer;
a second GaN-based layer disposed on the active layer; and
a second electrode disposed on the second GaN-based layer.

2. The light emitting element according to claim 1, wherein the substrate comprises one of a sapphire, a silicon, a quartz, an AlGaInN, an AlGaN, an InGaN, a GaN, an AlN, a BN, a CrN, a TiN, and a GaAs.

3. The light emitting element according to claim 1, wherein the first GaN-based layer comprises a compound of an nitrogen and one of an aluminum, a gallium, a indium, a boron, a thallium, and combinations thereof.

4. The light emitting element according to claim 1, wherein the first GaN-based layer is doped with n-type and p-type impurities and the second GaN-based layer is doped with the n-type and p-type impurities to have a conductivity opposite to that of the first GaN-based layer to form a p-n junction.

5. The light emitting element according to claim 1, wherein the dielectric thin film comprises a silicon oxynitride (SiOₓN_{y}).

6. The light emitting element according to claim 3, wherein the SiOₓN_{y} has a refractive index ranging from 1.4 to 2.

7. The light emitting element according to claim 3, wherein the SiOₓN_{y} has a refractive index ranging from 1.6 to 1.9.

8. The light emitting element according to claim 1, wherein the dielectric thin film comprises an aluminum oxide.

9. The light emitting element according to claim 1, wherein the embossed pattern is disposed to form a grid.

10. The light emitting element according to claim 1, wherein the embossed pattern has a shape of a circle or a polygon having n number of sides, where n>2.

11. The light emitting element according to claim 1, wherein a cross-section of the embossed pattern has a shape of a truncated ellipse, a truncated circle, a bell, a mongolian tent, a triangle or a polygon.

12. The light emitting element according to claim 1, wherein the embossed pattern is disposed to form a grid, the embossed pattern having a shape of a circle or a polygon being disposed at a vertex of the grid pattern.

13. The light emitting element according to claim 12, wherein the dielectric thin film
comprises a thin sub-film having a stripe pattern.

14. A method for fabricating a light emitting element, comprising steps of:
(a) forming a dielectric thin film including an embossed pattern on a substrate;
(b) sequentially growing a buffer layer, a first GaN-based layer, an active layer and a second GaN-based layer on the substrate and the dielectric thin film;
(c) depositing a current spreading layer on the second GaN-based layer and forming an ohmic contact via an annealing process;
(d) removing a portion of the current spreading layer, and the second GaN-based layer, the active layer and a predetermined thickness of the first GaN-based layer thereunder; and
(e) depositing a first electrode on an exposed portion of the first GaN layer and a second electrode on the current spreading layer.

15. The method according to claim 14, wherein the step (a) comprises:
(a-1) depositing the dielectric thin film on the substrate;
(a-2) forming a photoresist film pattern;
(a-3) reflowing the photoresist film pattern;
(a-4) transcribing the reflowed photoresist pattern into the dielectric thin film by etching the dielectric thin film to form the embossed pattern; and
(a-5) conducting a wet back etching process using a buffered oxide etchant to remove a portion of the dielectric thin film between embossed pattern.

16. The method according to claim 15, wherein the dielectric thin film comprises a silicon oxynitride (SiOₓN_{y}) or an aluminum oxide.

17. The method according to claim 15, wherein the substrate comprises a sapphire and the dielectric thin film comprise a silicon oxynitride film (SiOₓN_{y}) having a refractive index of 1.78.

18. The method according to claim 15, wherein the silicon oxynitride (SiOₓN_{y}) thin film has a composition determined by a ratio of an N₂O gas and an NH₃ gas or a ratio of an N₂ gas and an O₂ gas added to a SiH₄ gas.

19. The method according to claim 16, wherein the thin film comprising the aluminum oxide is formed via a sputtering process, a CVD process or an evaporation process.
